(19) United States
(12) Patent Application Publication
(10) Pub. No.: US 2026/0302088 A1
(43) Pub. Date: Oct. 1, 2026

(54) LC FILTER, DIPLEXER, HIGH FREQUENCY MODULE, AND COMMUNICATION DEVICE

(71) Applicant: Murata Manufacturing Co., Ltd., Nagaokakyo-shi (JP)

(72) Inventors: Akira TANAKA, Nagaokakyo-shi (JP); Hiroto MOTOYAMA, Nagaokakyo-shi (JP)

(21) Appl. No.: 19/541,824

(22) Filed: Feb. 17, 2026

(30) Foreign Application Priority Data
Mar. 27, 2025 (JP) 2025-053198

(51) Int. Cl. H01G 4/40; H01G 4/232; H03H 7/01

(52) U.S. Cl. CPC H01G 4/40; H01G 4/232; H03H 7/0115; H03H 7/1766

(57) ABSTRACT

An LC filter includes a first electrode, a second electrode, a first capacitor electrode, a second capacitor electrode, a third capacitor electrode, a first via connecting the first electrode and the first capacitor electrode, a second via connecting the first electrode and the second capacitor electrode, and a third via connecting the first electrode and the third capacitor electrode. The first capacitor electrode overlaps with a portion of each of the second electrode and the second capacitor electrode to define capacitors between the first capacitor electrode and each of the second electrode and the second capacitor electrode. The third capacitor electrode overlaps with a portion of the second capacitor electrode without overlapping with the second electrode to define a capacitor between the third capacitor electrode and the second capacitor electrode.

### CROSS REFERENCE TO RELATED APPLICATIONS

This application claims the benefit of priority to Japanese Patent Application No. 2025-053198 filed on Mar. 27, 2025. The entire contents of this application are hereby incorporated herein by reference.

### BACKGROUND OF THE INVENTION

### 1. Field of the Invention

The present t disclosure relates to LC filters each including a plurality of dielectric layers laminated therein, and diplexers, high frequency modules, and communication devices including the LC filters.

### 2. Description of the Related Art

There has heretofore been known an LC filter having a plurality of dielectric layers laminated therein. For example, International Publication No. 2023/145495 discloses a diplexer including a low pass filter to pass signals in a frequency band lower than a specific frequency and a high pass filter to pass signals in a frequency band higher than a specific frequency.

In the diplexer disclosed in International Publication No. 2023/145495, a plurality of capacitor electrodes are provided between flat plate-shaped first and second electrodes, and the plurality of capacitor electrodes are each connected to the first electrode through a plurality of vias. Each of the plurality of capacitor electrodes defines a capacitor between itself and the second electrode connected to ground. The plurality of vias form an inductor. In the diplexer, the low pass filter and the high pass filter are thus formed using the capacitors formed by the plurality of capacitor electrodes and the inductors formed by the plurality of vias.

According to the diplexer disclosed in International Publication No. 2023/145495, the low pass filter and the high pass filter can be formed. However, to obtain good frequency characteristics of an LC filter, further refinements to the LC filter structure are required.

### SUMMARY OF THE INVENTION

Example embodiments of the present invention provide techniques that make it possible to obtain good frequency characteristics of an LC filter.

An LC filter according to an example embodiment of the present disclosure includes a plurality of laminated dielectric layers, a flat plate-shaped first electrode provided in a first dielectric layer, a flat plate-shaped second electrode provided in a second dielectric layer, a flat plate-shaped first capacitor electrode provided in a third dielectric layer between the first dielectric layer and the second dielectric layer, a flat plate-shaped second capacitor electrode provided in a fourth dielectric layer between the first dielectric layer and the third dielectric layer, a flat plate-shaped third capacitor electrode provided in a dielectric layer between the first dielectric layer and the second dielectric layer, a first via connecting the first electrode and the first capacitor electrode, a second via connecting the first electrode and the second capacitor electrode, and a third via connecting the first electrode and the third capacitor electrode. In plan view of the first capacitor electrode from a lamination direction, the first capacitor electrode overlaps with a portion of each of the second electrode and the second capacitor electrode to define a capacitor between the first capacitor electrode and each of the second electrode and the second capacitor electrode. In plan view of the third capacitor electrode from the lamination direction, the third capacitor electrode overlaps with a portion of the second capacitor electrode without overlapping with the second electrode to define a capacitor between the third capacitor electrode and the second capacitor electrode.

A diplexer according to another example embodiment of the present disclosure includes a low pass filter to pass signals in a frequency band lower than a specific frequency, and a high pass filter to pass signals in a frequency band higher than the specific frequency. The LC filter defines and functions as at least one of the low pass filter and the high pass filter.

A high frequency module according to still another example embodiment of the present disclosure includes the LC filter, and an amplifier to amplify signals passed through the LC filter.

A communication device according to still another example embodiment of the present disclosure includes the high frequency module, and a signal processing circuit to process signals from the high frequency module.

In an LC filter according to an example embodiment of the present disclosure, the first capacitor electrode between the second electrode and the second capacitor electrode defines a capacitor between the first capacitor electrode and each of the second electrode and the second capacitor electrode, and the third capacitor electrode defines a capacitor between the third capacitor electrode and the second capacitor electrode. Furthermore, the third capacitor electrode and a portion of the second capacitor electrode that overlaps with the third capacitor electrode do not overlap with the second electrode. Therefore, no capacitor is provided between the second electrode and each of the third capacitor electrode and the second capacitor electrode. This allows an LC filter according to an example embodiment of the present disclosure to pass signals in a desired frequency band with better frequency characteristics than an LC filter configured such that each of the first capacitor electrode, the second capacitor electrode, and the third capacitor electrode defines a capacitor with the second electrode.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a diplexer according to a comparative example.

FIG. 2 is an enlarged view of a portion of a low pass filter according to the comparative example.

FIG. 3 is a schematic cross-sectional view of the portion of the low pass filter according to the comparative example.

FIG. 4 is a circuit diagram of the diplexer according to the comparative example.

FIG. 5 is a perspective view of a diplexer according to Example Embodiment 1 of the present invention.

FIG. 6 is an enlarged view of a portion of a low pass filter according to Example Embodiment 1 of the present invention.

FIG. 7 is a schematic cross-sectional view of the portion of the low pass filter according to Example Embodiment 1 of the present invention.

FIG. 8 is a circuit diagram of the low pass filter according to Example Embodiment 1 of the present invention.

FIG. 9 is a graph showing frequency characteristics of the diplexer according to Example Embodiment 1 of the present invention.

FIG. 10 is a schematic cross-sectional view of a portion of a low pass filter according to Modification 1 of Example Embodiment 1 of the present invention.

FIG. 11 is a schematic cross-sectional view of a portion of a low pass filter according to Modification 2 of Example Embodiment 1 of the present invention.

FIG. 12 is a diagram showing an example of a drilling process in the manufacture of LC filters.

FIG. 13 is a diagram showing an example of a printing process in the manufacture of LC filters.

FIG. 14 is a perspective view of a diplexer according to Example Embodiment 2 of the present invention.

FIG. 15 is a schematic cross-sectional view of a portion of a low pass filter according to Example Embodiment 2 of the present invention.

FIG. 16 is a graph showing frequency characteristics of the diplexer according to Example Embodiment 2 of the present invention.

FIG. 17 is a perspective view of a diplexer according to Modification 1 of Example Embodiment 2 of the present invention.

FIG. 18 is a schematic cross-sectional view of a portion of a low pass filter according to Modification 1 of Example embodiment 2 of the present invention.

FIG. 19 is a perspective view of a diplexer according to Modification 2 of Example Embodiment 2 of the present invention.

FIG. 20 is a schematic cross-sectional view of a portion of a low pass filter according to Modification 2 of Example Embodiment 2 of the present invention.

FIG. 21 is a perspective view of a diplexer according to Modification 3 of Example Embodiment 2 of the present invention.

FIG. 22 is a schematic cross-sectional view of a portion of a low pass filter according to Modification 3 of Example Embodiment 2 of the present invention.

FIG. 23 is a schematic cross-sectional view of a portion of a low pass filter according to Modification 4 of Example Embodiment 2 of the present invention.

FIG. 24 is a block diagram of a high frequency module including an LC filter and a communication device according to an example embodiment of the present invention.

### DETAILED DESCRIPTION OF THE EXAMPLE EMBODIMENTS

Example embodiments of the present disclosure will be described in detail below with reference to the drawings. Note that the same or corresponding elements, features, portions, etc., in the drawings are denoted by the same reference numerals, and repetitive description thereof will be omitted.

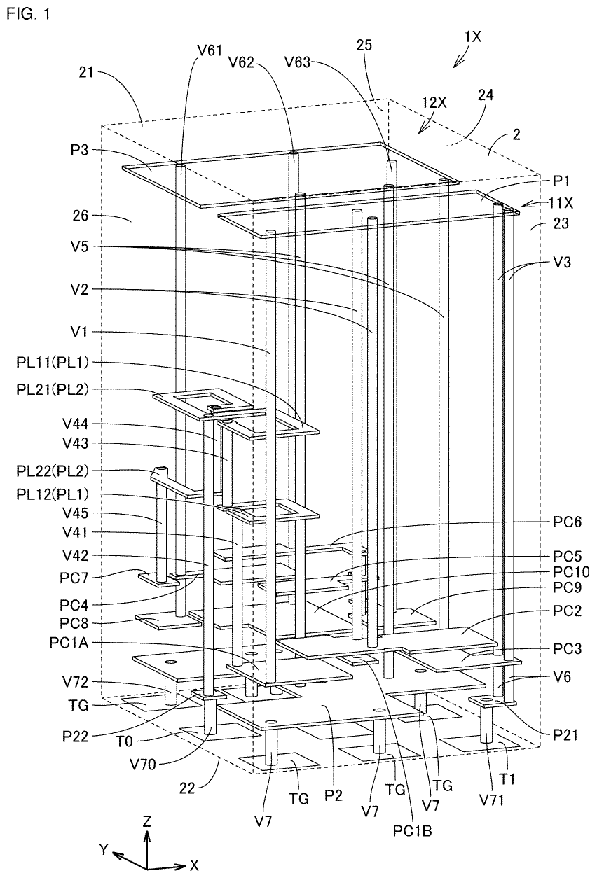

A diplexer 1X according to a comparative example will be described with reference to FIGS. 1 to 4. FIG. 1 is a perspective view of the diplexer 1X according to the comparative example.

As shown in FIG. 1, the diplexer 1X includes a multilayer body 2 including a plurality of dielectric layers (not shown) laminated therein. The multilayer body 2 has a rectangular parallelepiped shape or substantially rectangular parallelepiped shape. Specifically, the multilayer body 2 includes an upper surface 21, a lower surface 22 facing the upper surface 21, and a plurality of side surfaces 23, 24, 25, and 26 connecting the upper surface 21 and the lower surface 22. Note that the multilayer body 2 is not limited to such a rectangular parallelepiped shape or substantially rectangular parallelepiped shape, and may have any other three-dimensional shape. Hereinafter, the direction in which the plurality of dielectric layers are laminated will also be referred to as a lamination direction. The lamination direction corresponds to a direction normal to the upper surface 21 and the lower surface 22. A direction perpendicular to the lamination direction will also be referred to as a planar direction.

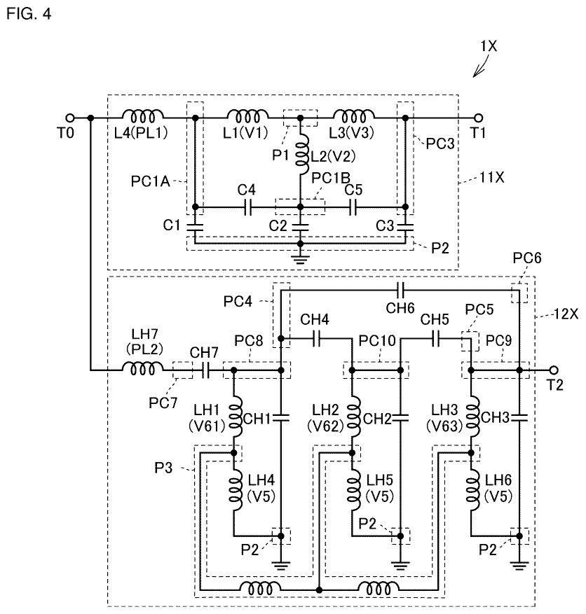

The plurality of dielectric layers each include ceramic, for example. Capacitors and inductors include a plurality of electrodes and a plurality of vias (via conductors) formed in the dielectric layers inside the multilayer body 2. The lower surface 22 is provided with a common terminal T0, a terminal T1, a terminal T2 (shown in FIG. 4), and a plurality of ground terminals TG. The common terminal T0, the terminal T1, and the terminal T2 are external terminals to connect the diplexer 1X to external devices (not shown). The ground terminals TG are connected to ground (reference potential).

The diplexer 1X includes a plurality of LC filters. An LC filter is a filter that uses a combination of a capacitor and an inductor to pass only signals in a specific frequency band among inputted signals. The diplexer 1X includes an LC filter that defines and functions as a low pass filter 11X to pass signals in a frequency band lower than a specific frequency, and an LC filter that defines and functions as a high pass filter 12X to pass signals in a frequency band higher than the specific frequency.

The low pass filter 11X includes a plurality of electrodes P1, P2, P21, and P22, a plurality of capacitor electrodes PC1A, PC1B, PC2, and PC3, an inductor pattern portion PL1, and a plurality of vias V1, V2, V3, V6, V7, V41, V42, V43, V70, and V71.

The electrode P1 is a flat plate-shaped electrode provided in a first dielectric layer near the upper surface 21 among the plurality of dielectric layers. The electrode P2 is a flat plate-shaped electrode provided in a second dielectric layer near the lower surface 22 among the plurality of dielectric layers.

The plurality of capacitor electrodes PC1A, PC1B, PC2, and PC3 are flat plate-shaped electrodes provided between the first dielectric layer in which the electrode P1 is provided and the second dielectric layer in which the electrode P2 is provided, among the plurality of dielectric layers. In the lamination direction, the capacitor electrodes PC1A, PC1B, and PC3 are disposed closer to the electrode P2 than the capacitor electrode PC2.

The inductor pattern portion PL1 is a helical coil including one or more turns. In the example of FIG. 1, the inductor pattern portion PL1 includes a pattern portion PL11 and a pattern portion PL12. The pattern portion PL11 and the pattern portion PL12 are disposed side by side in the lamination direction. The pattern portion PL11 and the pattern portion PL12 are each wound in the planar direction within different dielectric layers. In plan view of the pattern portion PL11 from the lamination direction, the pattern portion PL11 at least partially overlaps with the pattern portion PL12. The distance between the pattern portion PL11 and the pattern portion PL12, that is, the interlayer distance of the helical coil, is more than or equal to about 50 μm, for example.

The via V1 connects the electrode P1 and the capacitor electrode PC1A. The via V2 connects the electrode P1 and the electrode P2 through the capacitor electrode PC2. The via V3 connects the electrode P1 and the capacitor electrode PC3. The via V6 connects the capacitor electrode PC3 and the electrode P21. The via V7 connects the electrode P2 and the ground terminal TG. The via V41 connects the pattern portion PL12 and the capacitor electrode PC1A. The via V42 connects the pattern portion PL11 and the electrode P22. The via V43 connects the pattern portion PL11 and the pattern portion PL12. The via V70 connects the electrode P22 and the common terminal T0. The via V71 connects the electrode P21 and the terminal T1.

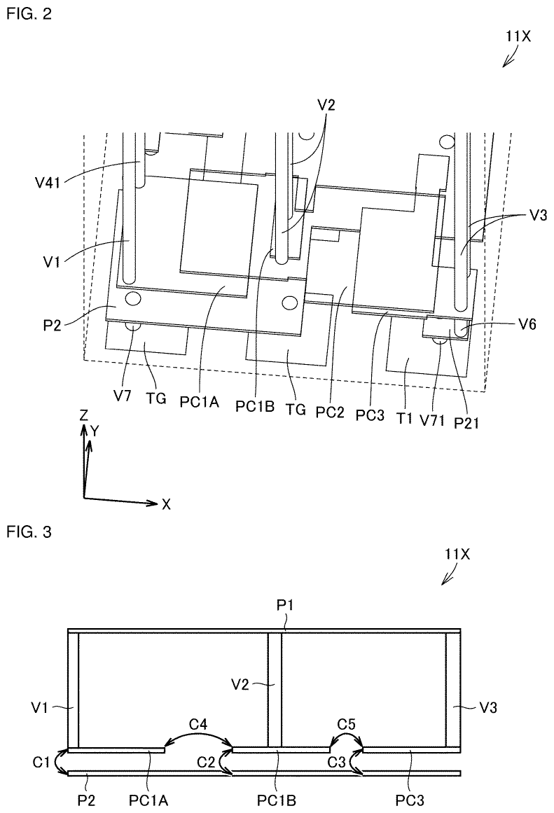

FIG. 2 is an enlarged view of a portion of the low pass filter 11X according to the comparative example. FIG. 3 is a schematic cross-sectional view of the portion of the low pass filter 11X according to the comparative example.

As shown in FIGS. 2 and 3, the capacitor electrodes PC1, PC2, and PC3 are provided between the first dielectric layer in which the electrode P1 is provided and the second dielectric layer in which the electrode P2 is provided. The electrode P2 is disposed directly below each of the capacitor electrodes PC1, PC2, and PC3.

In plan view of the capacitor electrode PC1A from the lamination direction, the capacitor electrode PC1A overlaps with a portion of the electrode P2. The space between the capacitor electrode PC1A and the electrode P2 in the lamination direction defines a capacitor C1.

In plan view of the capacitor electrode PC1B from the lamination direction, the capacitor electrode PC1B overlaps with a portion of the electrode P2. The space between the capacitor electrode PC1B and the electrode P2 in the lamination direction defines a capacitor C2.

In plan view of the capacitor electrode PC3 from the lamination direction, the capacitor electrode PC3 overlaps with a portion of the electrode P2. The space between the capacitor electrode PC3 and the electrode P2 in the lamination direction defines a capacitor C3.

The dielectric layer in which the capacitor electrode PC1B is provided is the same as the dielectric layer in which the capacitor electrode PC1A is provided. The space between the capacitor electrode PC1B and the capacitor electrode PC1A in the planar direction defines a capacitor C4.

The dielectric layer in which the capacitor electrode PC1B is provided is the same as the dielectric layer in which the capacitor electrode PC3 is provided. The space between the capacitor electrode PC1B and the capacitor electrode PC3 in the planar direction defines a capacitor C5.

Referring back to FIG. 1, a configuration of the high pass filter 12X will be described. As shown in FIG. 1, the high pass filter 12X includes a plurality of electrodes P2, P3, and P22, a plurality of capacitor electrodes PC4, PC5, PC6, PC7, PC8, PC9, and PC10, an inductor pattern portion PL2, and a plurality of vias V5, V7, V42, V44, V45, V61, V62, V63, V70, and V72.

The electrode P3 is a flat plate-shaped electrode provided in the first dielectric layer near the upper surface 21 among the plurality of dielectric layers.

The plurality of capacitor electrodes PC4, PC5, PC6, PC7, PC8, PC9, and PC10 are flat plate-shaped electrodes provided between the first dielectric layer in which the electrode P3 is provided and the second dielectric layer in which the electrode P2 is provided, among the plurality of dielectric layers. In the lamination direction, the capacitor electrodes PC8, PC9, and PC10 are disposed closer to the electrode P2 than the capacitor electrodes PC4, PC5, PC6, and PC7.

The inductor pattern portion PL2 is a helical coil including one or more turns. In the example of FIG. 1, the inductor pattern portion PL2 includes a pattern portion PL21 and a pattern portion PL22. The pattern portion PL21 and the pattern portion PL22 are disposed side by side in the lamination direction. The pattern portion PL21 and the pattern portion PL22 are each wound in the planar direction within different dielectric layers. In plan view of the pattern portion PL21 from the lamination direction, the pattern portion PL21 at least partially overlaps with the pattern portion PL22. The distance between the pattern portion PL21 and the pattern portion PL22, that is, the interlayer distance of the helical coil, is more than or equal to about 50 μm, for example.

The via V5 connects the electrode P3 and the electrode P2. The via V7 connects the electrode P2 and the terminal T2. The via V42 connects the pattern portion PL21 and the electrode P22. The via V44 connects the pattern portion PL21 and the pattern portion PL22. The via V45 connects the pattern portion PL22 and the capacitor electrode PC7. The via V61 connects the electrode P3 and the capacitor electrode PC8. The via V62 connects the electrode P3 and the capacitor electrode PC10. The via V63 connects the electrode P3 and the capacitor electrode PC9. The via V70 connects the electrode P22 and the common terminal T0. The via V72 connects the electrode P2 and the terminal T2.

In plan view of the capacitor electrode PC8 from the lamination direction, the capacitor electrode PC8 overlaps with a portion of the electrode P2. The space between the capacitor electrode PC8 and the electrode P2 in the lamination direction defines a capacitor CH1.

In plan view of the capacitor electrode PC10 from the lamination direction, the capacitor electrode PC10 overlaps with a portion of the electrode P2. The space between the capacitor electrode PC10 and the electrode P2 in the lamination direction defines a capacitor CH2.

In plan view of the capacitor electrode PC9 from the lamination direction, the capacitor electrode PC9 overlaps with a portion of the electrode P2. The space between the capacitor electrode PC9 and the electrode P2 in the lamination direction defines a capacitor CH3.

In plan view of the capacitor electrode PC4 from the lamination direction, the capacitor electrode PC4 overlaps with a portion of the capacitor electrode PC10. The space between the capacitor electrode PC4 and the capacitor electrode PC10 in the lamination direction defines a capacitor CH4.

In plan view of the capacitor electrode PC10 from the lamination direction, the capacitor electrode PC10 overlaps with a portion of the capacitor electrode PC5. The space between the capacitor electrode PC10 and the capacitor electrode PC5 in the lamination direction defines a capacitor CH5.

In plan view of the capacitor electrode PC6 from the lamination direction, the capacitor electrode PC6 overlaps with a portion of the capacitor electrode PC4. The space between the capacitor electrode PC6 and the capacitor electrode PC4 in the lamination direction defines a capacitor CH6.

In plan view of the capacitor electrode PC7 from the lamination direction, the capacitor electrode PC7 overlaps with a portion of the capacitor electrode PC8. The space between the capacitor electrode PC7 and the capacitor electrode PC8 in the lamination direction defines a capacitor CH7.

FIG. 4 is a circuit diagram of the diplexer 1X according to the comparative example. As shown in FIG. 4, the low pass filter 11X is connected between the common terminal T0 and the terminal T1, and includes the capacitors C1, C2, C3, C4, and C5, and inductors L1, L2, L3, and L4.

The capacitor C1 is provided between the capacitor electrode PC1A and the electrode P2 by capacitive coupling between the capacitor electrode PC1A and the electrode P2.

The capacitor C2 is provided between the capacitor electrode PC1B and the electrode P2 by capacitive coupling between the capacitor electrode PC1B and the electrode P2.

The capacitor C3 is provided between the capacitor electrode PC3 and the electrode P2 by capacitive coupling between the capacitor electrode PC3 and the electrode P2. The capacitor C3 is connected to the terminal T1.

The capacitor C4 is provided between the capacitor electrode PC1A and the capacitor electrode PC1B by capacitive coupling between the capacitor electrode PC1A and the capacitor electrode PC1B.

The capacitor C5 is provided between the capacitor electrode PC1B and the capacitor electrode PC3 by capacitive coupling between the capacitor electrode PC1B and the capacitor electrode PC3.

The inductor L1 includes the via V1 connected between the capacitor electrode PC1A and the electrode P1.

The inductor L2 includes the via V2 connected between the capacitor electrode PC1B and the electrode P1.

The inductor L3 includes the via V3 connected between the capacitor electrode PC3 and the electrode P1.

The inductor L4 includes the inductor pattern portion PL1 connected between the common terminal T0 and the capacitor electrode PC1A.

The high pass filter 12X is connected between the common terminal T0 and the terminal T2, and includes the capacitors CH1, CH2, CH3, CH4, CH5, CH6, and CH7, and inductors LH1, LH2, LH3, LH4, LH5, LH6, and LH7.

The capacitor CH1 is provided between the capacitor electrode PC8 and the electrode P2 by capacitive coupling between the capacitor electrode PC8 and the electrode P2.

The capacitor CH2 is provided between the capacitor electrode PC10 and the electrode P2 by capacitive coupling between the capacitor electrode PC10 and the electrode P2.

The capacitor CH3 is provided between the capacitor electrode PC9 and the electrode P2 by capacitive coupling between the capacitor electrode PC9 and the electrode P2.

The capacitor CH4 is provided between the capacitor electrode PC4 and the capacitor electrode PC10 by capacitive coupling between the capacitor electrode PC4 and the capacitor electrode PC10.

The capacitor CH5 is provided between the capacitor electrode PC10 and the capacitor electrode PC5 by capacitive coupling between the capacitor electrode PC10 and the capacitor electrode PC5.

The capacitor CH6 is provided between the capacitor electrode PC4 and the capacitor electrode PC6 by capacitive coupling between the capacitor electrode PC4 and the capacitor electrode PC6.

The capacitor CH7 is provided between the capacitor electrode PC7 and the capacitor electrode PC8 by capacitive coupling between the capacitor electrode PC7 and the capacitor electrode PC8.

The inductor LH1 includes the via V61 connected between the capacitor electrode PC8 and the electrode P3.

The inductor LH2 includes the via V62 connected between the capacitor electrode PC10 and the electrode P3.

The inductor LH3 includes the via V63 connected between the capacitor electrode PC9 and the electrode P3.

The inductors LH4, LH5, and LH6 are each formed by a plurality of vias V5 connected between the electrode P3 and the electrode P2.

The inductor LH7 includes the inductor pattern portion PL2 connected between the common terminal T1 and the capacitor electrode PC7.

In the diplexer 1X configured as described above, the low pass filter 11X passes only signals in a frequency band lower than a specific frequency, among signals inputted from the common terminal T0, and outputs the signals through the terminal T1. Also, in the diplexer 1X, the high pass filter 12X passes only signals in a frequency band higher than the specific frequency, among the signals inputted from the common terminal T0, and outputs the signals through the terminal T2. Note that the vias or capacitor electrodes of the high pass filter 12X inside the multilayer body 2 may have parasitic components with other vias or circuit electrodes disposed nearby. This can result in pass loss on the high-frequency side of the pass band of the high pass filter 12X.

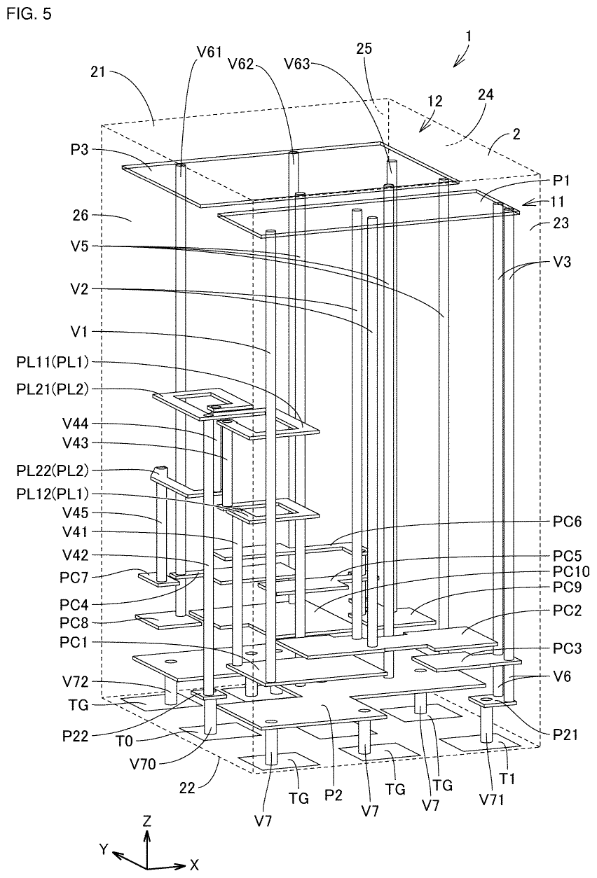

A diplexer 1 according to Example Embodiment 1 will be described with reference to FIGS. 5 to 11. Hereinafter, only differences between the diplexer 1 according to Example Embodiment 1 and the diplexer 1X according to the comparative example will be described, and description of similarities to the diplexer 1X according to the comparative example may be omitted.

Depending on the frequency band in which the diplexer 1X according to the comparative example is used, further refinements to the LC filter structure are required to achieve good frequency characteristics of the LC filter. For example, if the diplexer 1X according to the comparative example is designed for use in a 5 GHz band, using the diplexer 1X in a frequency band other than the 5 GHz band (such as a 6 GHz band) makes it difficult to achieve good frequency characteristics.

Specifically, in the diplexer 1X, the attenuation pole of the low pass filter 11X is determined by the resonant frequency of the inductors L1, L2, and L3 and the capacitors C1, C2, and C3. More specifically, the frequency is determined by Formula (1) below. Therefore, as for the ratio of L to C, the larger the L, the larger the attenuation.

$$f = 1 / 2 \prod √ L \times C \qquad ( 1 )$$

In a case of using the diplexer 1X according to the comparative example in the 6 GHz band, the capacitors C2 and C3 formed by capacitive coupling with the electrode P2 at the ground potential become larger than desired, forcing the inductors L1, L2, and L3 (vias V1, V2, and V3) to be smaller than necessary.

It has been discovered that the capacitors C2 and C3 are not necessarily required in the case of using the diplexer 1X in the 6 GHz band. Furthermore, in the diplexer 1X, the capacitors C2 and C3 are designed with smaller values than the capacitor C1. Therefore, as shown in FIG. 2, each of the capacitor electrodes PC1B and PC3 needs to have a long, stub-like shape, which causes unwanted resonance of harmonic waves.

On the other hand, the diplexer 1 according to Example Embodiment 1 is configured to achieve good frequency characteristics without causing unwanted resonance of harmonic waves in a predetermined frequency band (for example, 6 GHZ band).

FIG. 5 is a perspective view of the diplexer 1 according to Example Embodiment 1. When the diplexer 1X according to the comparative example shown in FIG. 1 is compared with the diplexer 1 according to Example Embodiment 1 shown in FIG. 5, the diplexer 1 according to Example Embodiment 1 differs from the diplexer 1X in that a low pass filter 11 includes a capacitor electrode PC1, instead of capacitor electrodes PC1A and PC1B.

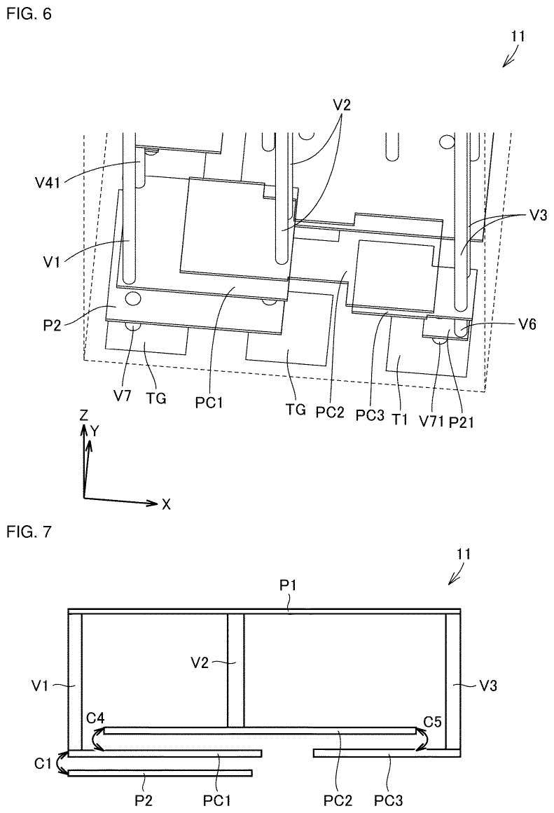

FIG. 6 is an enlarged view of a portion of the low pass filter 11 according to Example Embodiment 1. FIG. 7 is a schematic cross-sectional view of the portion of the low pass filter 11 according to Example Embodiment 1. As shown in FIGS. 6 and 7, the low pass filter 11 includes electrodes P1 and P2, capacitor electrodes PC1, PC2, and PC3, and vias V1, V2, and V3.

The electrode P1 is an example of a “first electrode”, and is a flat plate-shaped electrode provided in a first dielectric layer near an upper surface 21 among a plurality of dielectric layers. The electrode P2 is an example of a “second electrode”, and is a flat plate-shaped electrode provided in a second dielectric layer near a lower surface 22 among the plurality of dielectric layers.

The capacitor electrode PC1 is an example of a “first capacitor electrode”, and is a flat plate-shaped electrode provided in a third dielectric layer between the first dielectric layer in which the electrode P1 is provided and the second dielectric layer in which the electrode P2 is provided, among the plurality of dielectric layers. The electrode P2 is disposed directly below the capacitor electrode PC1.

The capacitor electrode PC2 is an example of a “second capacitor electrode”, and is a flat plate-shaped electrode provided in a fourth dielectric layer between the first dielectric layer in which the electrode P1 is provided and the third dielectric layer in which the capacitor electrode PC1 is provided, among the plurality of dielectric layers. The capacitor electrodes PC1 and PC3 are disposed directly below the capacitor electrode PC2.

The capacitor electrode PC3 is an example of a “third capacitor electrode”, and is a flat plate-shaped electrode provided in a dielectric layer between the first dielectric layer in which the electrode P1 is provided and the second dielectric layer in which the electrode P2 is provided, among the plurality of dielectric layers. In the example of FIG. 7, the capacitor electrode PC3 is provided in the third dielectric layer in which the capacitor electrode PC1 is provided. Note that the electrode P2 is not disposed directly below the capacitor electrode PC3.

The via V1 is an example of a “first via”, and connects the electrode P1 and the capacitor electrode PC1. The via V2 is an example of a “second via”, and connects the electrode P1 and the capacitor electrode PC2. The via V3 is an example of a “third via”, and connects the electrode P1 and the capacitor electrode PC3.

In plan view of the capacitor electrode PC1 from the lamination direction, the capacitor electrode PC1 overlaps with a portion of the electrode P2 to define a capacitor C1 between the capacitor electrode PC1 and the electrode P2. Furthermore, in plan view of the capacitor electrode PC1 from the lamination direction, the capacitor electrode PC1 overlaps with a portion of the capacitor electrode PC2 to define a capacitor C4 between the capacitor electrode PC1 and the capacitor electrode PC2.

In plan view of the capacitor electrode PC3 from the lamination direction, the capacitor electrode PC3 overlaps with a portion of the capacitor electrode PC2 to define a capacitor C5 between the capacitor electrode PC3 and the capacitor electrode PC2. The electrode P2 is not disposed directly below the capacitor electrode PC3. Therefore, in plan view of the capacitor electrode PC3 from the lamination direction, the capacitor electrode PC3 does not overlap with the electrode P2. As a result, no capacitor is provided between the capacitor electrode PC3 and the electrode P2.

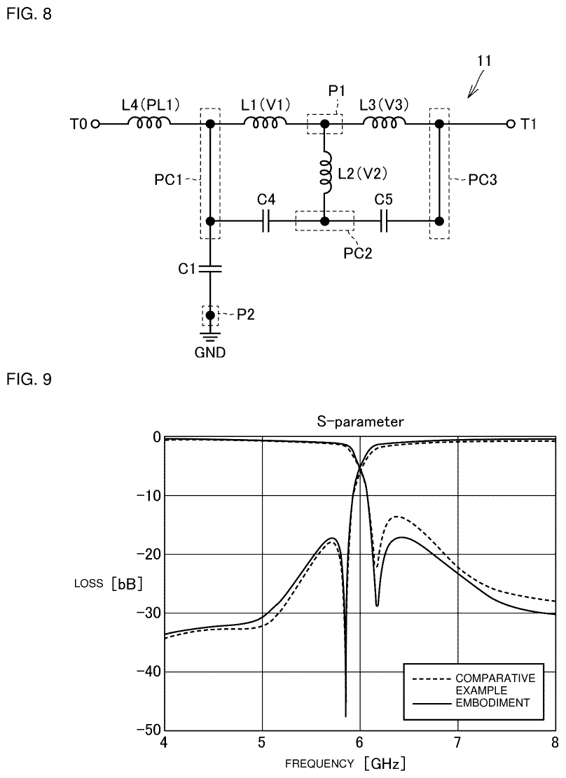

FIG. 8 is a circuit diagram of the low pass filter 11 according to Example Embodiment 1. As shown in FIG. 8, the low pass filter 11 is connected between a common terminal T0 and a terminal T1, and includes the capacitors C1, C4, and C5, and inductors L1, L2, L3, and L4.

The capacitor C1 is provided between the capacitor electrode PC1 and the electrode P2 by capacitive coupling between the capacitor electrode PC1 and the electrode P2.

The capacitor C4 is provided between the capacitor electrode PC1 and the capacitor electrode PC2 by capacitive coupling between the capacitor electrode PC1 and the capacitor electrode PC2.

The capacitor C5 is provided between the capacitor electrode PC2 and the capacitor electrode PC3 by capacitive coupling between the capacitor electrode PC2 and the capacitor electrode PC3.

The inductor L1 includes the via V1 connected between the capacitor electrode PC1 and the electrode P1.

The inductor L2 includes the via V2 connected between the capacitor electrode PC2 and the electrode P1.

The inductor L3 includes the via V3 connected between the capacitor electrode PC3 and the electrode P1.

The inductor L4 includes an inductor pattern portion PL1 connected between the common terminal T0 and the capacitor electrode PC1.

As such, no capacitors C2 and C3 are provided in the low pass filter 11 of the diplexer 1 according to Example Embodiment 1. This allows the diplexer 1 to provide the low pass filter 11 that can be used in a 6 GHz band.

Furthermore, the low pass filter 11 of the diplexer 1 has the capacitor electrode PC2 disposed directly above the capacitor electrodes PC1 and PC3. Accordingly, the capacitor C4 includes capacitive coupling between the capacitor electrode PC2 and the capacitor electrode PC1. The capacitor C5 is also provided by capacitive coupling between the capacitor electrode PC2 and the capacitor electrode PC3. This eliminates the need for the capacitor electrodes PC1B and PC3 having an elongated stub-like shape to be provided in the diplexer 1, compared to the diplexer 1X according to the comparative example, making it possible to reduce unwanted resonance of harmonic waves.

FIG. 9 is a graph showing frequency characteristics of the diplexer 1 according to Example Embodiment 1. FIG. 9 is a graph with frequency [GHz] on the horizontal axis and loss [dB] on the vertical axis, showing the loss versus the frequency of signals passing through each of the diplexers 1 and 100. In FIG. 9, the frequency characteristics of the diplexer 1X according to the comparative example are shown by a dashed line, while the frequency characteristics of the diplexer 1 according to Example Embodiment 1 are shown by a solid line.

As shown in FIG. 9, the high pass filter 12 of the diplexer 1 according to Example Embodiment 1 and the high pass filter 12X of the diplexer 1X according to the comparative example have roughly the same attenuation in the frequency band below 6 GHz. On the other hand, the low pass filter 11 of the diplexer 1 according to Example Embodiment 1 can achieve larger attenuation in a frequency band at or above 6 GHz than the low pass filter 11X of the diplexer 1X according to the comparative example. That is, the diplexer 1 according to Example Embodiment 1 can achieve better frequency characteristics in the 6 GHz band than the diplexer 1x according to the comparative example.

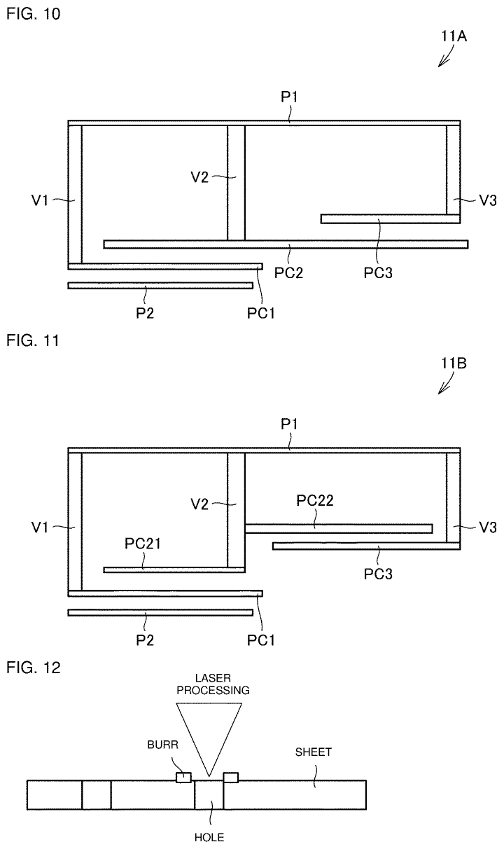

FIG. 10 is a schematic cross-sectional view of a portion of a low pass filter 11A according to Modification 1 of Example Embodiment 1. Hereinafter, only differences between the low pass filter 11A according to Modification 1 of Example Embodiment 1 and the low pass filter 11 shown in FIG. 7 will be described, and description of similarities to the low pass filter 11 shown in FIG. 7 may be omitted.

As shown in FIG. 10, in the low pass filter 11A, a capacitor electrode PC3 is provided in a fifth dielectric layer between a first dielectric layer in which an electrode P1 is provided and a fourth dielectric layer in which a capacitor electrode PC2 is provided, among a plurality of dielectric layers.

In plan view of the capacitor electrode PC3 from the lamination direction, the capacitor electrode PC3 overlaps with a portion of the capacitor electrode PC2 to define a capacitor C5 between the capacitor electrode PC3 and the capacitor electrode PC2. The capacitor electrode PC2 is disposed directly below the capacitor electrode PC3. The electrode P2 is not disposed directly below the portion of the capacitor electrode PC2 that overlaps with the capacitor electrode PC3 in the lamination direction. Therefore, in plan view of the capacitor electrode PC3 from the lamination direction, the capacitor electrode PC3 does not overlap with the electrode P2.

The low pass filter 11A as shown in FIG. 10 can also achieve larger attenuation in the frequency band at or above 6 GHZ than the low pass filter 11 according to the comparative example, thus achieving good frequency characteristics in the 6 GHz band.

FIG. 11 is a schematic cross-sectional view of a portion of a low pass filter 11B according to Modification 2 of Example Embodiment 1. Hereinafter, only differences between the low pass filter 11B according to Modification 2 of Example Embodiment 1 and the low pass filter 11 shown in FIG. 7 will be described, and description of similarities to the low pass filter 11 shown in FIG. 7 may be omitted.

As shown in FIG. 11, in the low pass filter 11B, a capacitor electrode PC2 is divided into a capacitor electrode PC21 and a capacitor electrode PC22, which are provided in two layers.

The capacitor electrode PC21 is an example of a “first capacitor portion”, and is provided in a fourth dielectric layer between a first dielectric layer in which an electrode P1 is provided and a third dielectric layer in which a capacitor electrode PC1 is provided. The capacitor electrode PC22 is an example of a “second capacitor portion”, and is provided in a sixth dielectric layer different from the fourth dielectric layer. The fourth dielectric layer in which the capacitor electrode PC21 is provided is closer to a second dielectric layer in which an electrode P2 is provided in the lamination direction than the sixth dielectric layer in which the capacitor electrode PC22 is provided.

In plan view of the capacitor electrode PC21 from the lamination direction, the capacitor electrode PC21 overlaps with a portion of the capacitor electrode PC1 to define a capacitor C4 between the capacitor electrode PC21 and the capacitor electrode PC1.

In plan view of the capacitor electrode PC22 from the lamination direction, the capacitor electrode PC22 overlaps with a portion of the capacitor electrode PC3 to define a capacitor C5 between the capacitor electrode PC22 and the capacitor electrode PC3. The electrode P2 is not disposed directly below the capacitor electrode PC3. Therefore, in plan view of the capacitor electrode PC3 from the lamination direction, the capacitor electrode PC3 does not overlap with the electrode P2.

The low pass filter 11B as shown in FIG. 11 can also achieve larger attenuation in the frequency band at or above 6 GHZ than the low pass filter 11 according to the comparative example, thus achieving good frequency characteristics in the 6 GHz band.

The diplexer 1 according to Example Embodiment 1 described above is characterized by the configurations of the low pass filters 11, 11A, and 11B. However, the high pass filter 12 may also have the same characteristics as the low pass filters 11, 11A, and 11B. In other words, the LC filters according to example embodiments of the present disclosure are not limited to functioning as the low pass filters 11, 11A, and 11B, and may also function as the high pass filter 12.

In this case, the electrode P3 may correspond to the “first electrode”, and the electrode P2 may correspond to the “second electrode”. The capacitor electrode PC8 may correspond to the “first capacitor electrode”, the capacitor electrode PC10 may correspond to the “second capacitor electrode”, and the capacitor electrode PC9 may correspond to the “third capacitor electrode”. The via V61 connecting the electrode P3 and the capacitor electrode PC8 may correspond to the “first via”, the via V62 connecting the electrode P3 and the capacitor electrode PC10 may correspond to the “second via”, and the via V63 connecting the electrode P3 and the capacitor electrode PC9 may correspond to the “third via”. In plan view of the capacitor electrode PC8 from the lamination direction, the capacitor electrode PC8 overlaps with a portion of each of the electrode P2 and the capacitor electrode PC10 to define a capacitor between the capacitor electrode PC8 and each of the electrode P2 and the capacitor electrode PC8. Furthermore, in plan view of the capacitor electrode PC9 from the lamination direction, the capacitor electrode PC9 may form a capacitor between the capacitor electrode PC9 and the capacitor electrode PC10 by overlapping with a portion of the capacitor electrode PC10 without overlapping with the electrode P2.

As described above, in the diplexer 1 according to Example Embodiment 1, an LC filter according to an example embodiment of the present disclosure may define and function as at least one of the low pass filters 11, 11A, and 11B and the high pass filter 12.

A diplexer 10 according to Example Embodiment 2 will be described with reference to FIGS. 12 to 23. Hereinafter, only differences between the diplexer 10 according to Example Embodiment 2 and the diplexer 1X according to the comparative example will be described, and description of similarities to the diplexer 1X according to the comparative example may be omitted.

FIG. 12 is a diagram showing an example of a drilling process in the manufacture of LC filters. As shown in FIG. 12, in the manufacture of LC filters, laser processing is performed on a ceramic sheet of a dielectric layer to form a hole for a via to pass therethrough in the sheet. During this process, burrs may occur on the laser-processed sheet.

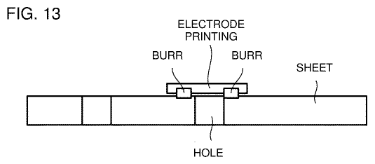

FIG. 13 is a diagram showing an example of a printing process in the manufacture of LC filters. As shown in FIG. 13, if conductive paste is applied for printing to form an electrode pattern on a sheet with burrs, bleeding may occur during electrode printing. As shown in FIG. 9, the diplexer 1X according to the comparative example is characterized by a very small difference between the frequency of the signal attenuation pole of the low pass filter 11X and the frequency of the signal attenuation pole of the high pass filter 12X. If bleeding during electrode printing as described above causes dimensional variations in electrodes formed on the sheet, the frequency characteristics of the diplexer 1X may deteriorate, potentially resulting in problems such as an increase in the difference between the frequency of the signal attenuation pole of the low pass filter 11X and the frequency of the signal attenuation pole of the high pass filter 12X.

On the other hand, the diplexer 10 according to Example Embodiment 2 is configured to achieve good frequency characteristics by reducing the number of vias (holes) compared to the diplexer 1X according to the comparative example to reduce bleeding during electrode printing.

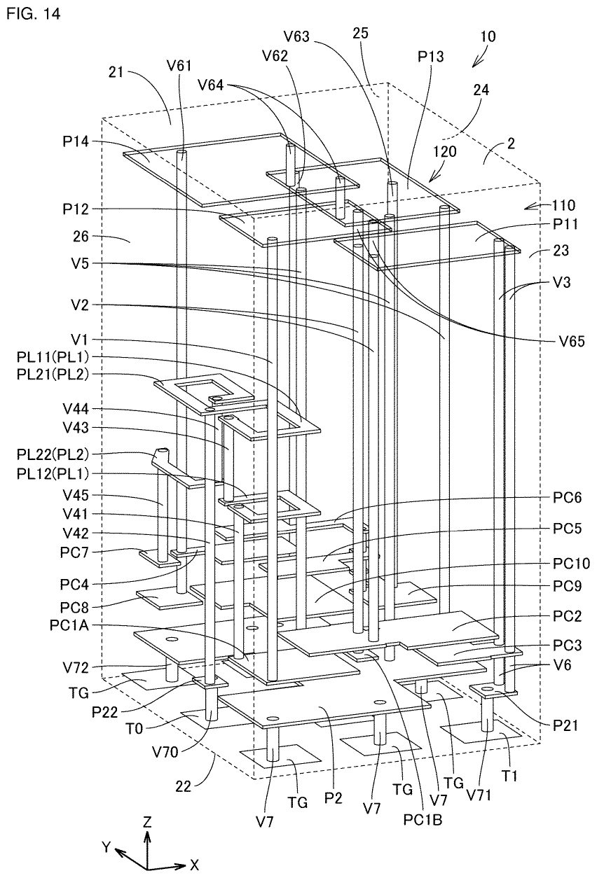

FIG. 14 is a perspective view of the diplexer 10 according to Example Embodiment 2. When the diplexer 1X according to the comparative example shown in FIG. 1 is compared with the diplexer 10 according to Example Embodiment 2 shown in FIG. 14, the diplexer 10 differs from the diplexer 1X according to the comparative example in that an electrode P1 includes a plurality of electrodes P11 and P12 and a via V65 connecting the electrode P11 and the electrode P12 is provided in a low pass filter 110.

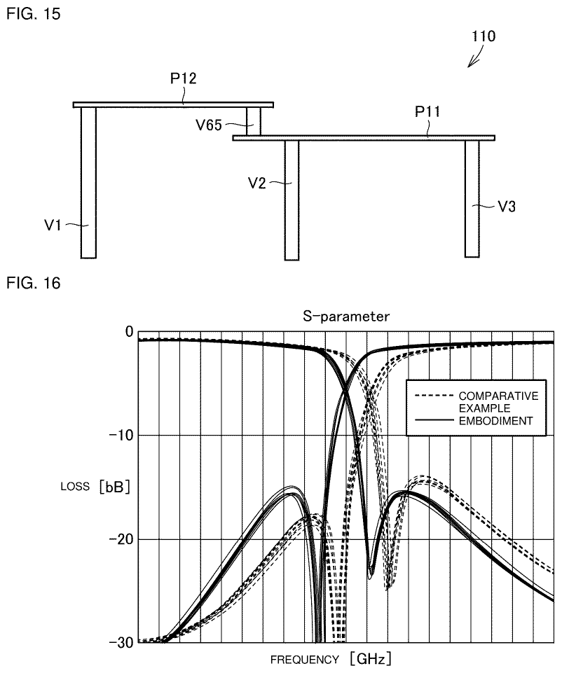

FIG. 15 is a schematic cross-sectional view of a portion of the low pass filter 110 according to Example Embodiment 2. As shown in FIGS. 14 and 15, the low pass filter 110 includes the electrodes P11 and P12 and vias V1, V2, V3, and V65.

The electrode P12 is an example of a “first electrode portion”, and is a flat plate-shaped electrode provided near an upper surface 21 among a plurality of dielectric layers. The electrode P11 is an example of a “second electrode portion”, and is a flat plate-shaped electrode provided below the electrode P12 in the lamination direction. In other words, the electrode corresponding to the “first electrode” may include a two-layer structure including the plurality of electrodes P11 and P12.

The via V1 is an example of a “first via”, and connects the electrode P12 and a capacitor electrode PC1A. The via V2 is an example of a “second via”, and connects the electrode P11 and a capacitor electrode PC2. The via V3 is an example of a “third via”, and connects the electrode P11 and a capacitor electrode PC3. The via V65 is an example of a “first connection via”, and connects the electrode P11 and the electrode P12. The via V65 is shorter than the vias V1, V2, and V3.

Furthermore, in the low pass filter 110, at least one of the vias V1, V2, and V3 is connected to the electrode P11. In the example of FIGS. 14 and 15, the via V1 is connected to the electrode P12, and the vias V2 and V3 are connected to the electrode P11. In this case, the number of holes formed in each of the electrodes P11 and P12 is two.

By providing a step between the separate electrodes P11 and P12, only two holes are provided in the electrode P12 to connect the two vias V1 and V65, and only two holes are provided in the electrode P11 to connect the two vias V2 and V3. This makes it possible to reduce the number of holes formed in one sheet, compared to the case where three holes are provided in the electrode P1 to connect the three vias V1, V2, and V3, as in the low pass filter 11X according to the comparative example. This can reduce bleeding during electrode printing when conductive paste is applied for printing to form the electrode pattern of the electrode P11 or electrode P12 on the sheet, resulting in good frequency characteristics.

By adjusting the distance between the electrode P11 and the electrode P12, the lengths of the vias V1, V2, V3, and V65 can be adjusted. As a result, the inductance of the low pass filter 110 can be adjusted. By making the via V65 shorter than the vias V1, V2, and V3, the vias V1, V2, and V3 can be appropriately lengthened, thus ensuring appropriate inductance of the low pass filter 110. Furthermore, by dividing the electrode into two layers, the area per layer in the planar direction can be reduced, and dimensional variations in the electrodes can be “reduced or prevented.

The diplexer 10 according to Example Embodiment 2 described above is characterized by the configuration of the low pass filter 110. However, a high pass filter 120 may also have the same characteristics as the low pass filter 110. In other words, an LC filter according to an example embodiment of the present disclosure is not limited to functioning as the low pass filter 110, but may also function as the high pass filter 120.

When the diplexer 1X according to the comparative example shown in FIG. 1 is compared with the diplexer 10 according to Example Embodiment 2 shown in FIG. 14, the diplexer 10 differs from the diplexer 1X in that an electrode P3 includes a plurality of electrodes P13 and P14 and a via V64 connecting the electrode P13 and the electrode P14 is provided in the high pass filter 120.

The electrode P14 is an example of a “first electrode portion”, and is a flat plate-shaped electrode provided near the upper surface 21 among the plurality of dielectric layers. The electrode P13 is an example of a “second electrode portion”, and is a flat plate-shaped electrode provided below the electrode P14 in the lamination direction. That is, the electrode corresponding to the “first electrode” preferably a two-layer structure including the plurality of electrodes P13 and P14.

A via V61 is an example of a “first via”, and connects the electrode P14 and a capacitor electrode PC8. A via V62 is an example of a “second via”, and connects the electrode P13 and a capacitor electrode PC10. A via V63 is an example of a “third via”, and connects the electrode P13 and a capacitor electrode PC9. The via V64 is an example of a “first connection via”, and connects the electrode P13 and the electrode P14. The via V64 is shorter than the vias V61, V62, and V63.

Furthermore, in the high pass filter 120, at least one of the vias V61, V62, and V63 is connected to the electrode P13. In the example of FIG. 14, the via V61 is connected to the electrode P14, and the vias V62 and V63 are connected to the electrode P13. In this case, the number of holes formed in each of the electrodes P13 and P14 is two.

By providing a step between the separate electrodes P13 and P14, only two holes are provided in the electrode P14 to connect the two vias V61 and V64, and only two holes are provided in the electrode P13 to connect the two vias V62 and V63. This makes it possible to reduce the number of holes formed in one sheet, compared to the case where three holes are provided in the electrode P3 to connect the three vias V61, V62, and V63, as in the high pass filter 12X according to the comparative example. This can reduce bleeding during electrode printing when conductive paste is applied for printing to form the electrode pattern of the electrode P13 or electrode P14 on the sheet, resulting in good frequency characteristics.

By adjusting the distance between the electrode P13 and the electrode P14, the lengths of the vias V61, V62, V63, and V64 can be adjusted. As a result, the inductance of the high pass filter 120 can be adjusted. By making the via V64 shorter than the vias V61, V62, and V63, the vias V61, V62, and V63 can be appropriately lengthened, thus ensuring appropriate inductance of the high pass filter 120. Furthermore, by dividing the electrode into two layers, the area per layer in the planar direction can be reduced, and dimensional variations in the electrodes can be “reduced or prevented.

FIG. 16 is a graph showing the frequency characteristics of the diplexer 10 according to Example Embodiment 2. FIG. 16 is a graph with frequency [GHz] on the horizontal axis and loss [dB] on the vertical axis, showing the loss versus the frequency of signals passing through each of the diplexers 1X and 10. One graduation on the scale of the horizontal axis is 100 MHz, and the center frequency on the horizontal axis is 5 GHZ. In FIG. 16, the frequency characteristics of the diplexer 1X according to the comparative example are shown by a dashed line, while the frequency characteristics of the diplexer 10 according to Example Embodiment 2 are shown by a solid line. Furthermore, FIG. 16 shows the frequency characteristics of each of the diplexers 1X and 10 obtained using a plurality of individual units.

As shown in FIG. 16, variations in frequency characteristics of the high pass filter 120 of the diplexer 10 according to Example Embodiment 2 are smaller than variations in frequency characteristics of the high pass filter 120 of the diplexer 1X according to the comparative example. Furthermore, variations in frequency characteristics of the low pass filter 110 of the diplexer 10 according to Example Embodiment 2 are smaller than variations in frequency characteristics of the low pass filter 11X of the diplexer 1X according to the comparative example.

For example, in the example of FIG. 16, the standard deviation of the frequency in the 5 GHz band of the diplexer 1X according to the comparative example is 14.1 MHz, while the standard deviation of the frequency in the 5 GHz band of the diplexer 10 according to Example Embodiment 2 is 9.8 MHz. Thus, the diplexer 10 according to Example Embodiment 2 can achieve better frequency characteristics than the diplexer 1X according to the comparative example by suppressing variations in frequency characteristics.

The features of the diplexer 10 according to Example Embodiment 2 described above may be combined with the features of the diplexer 1 according to Example Embodiment 1 shown in FIGS. 5 to 11. That is, the configuration near the upper surface 21 of the diplexer 10 according to Example Embodiment 2 may be combined with the configuration near the lower surface 22 of the diplexer 1 according to Example Embodiment 1.

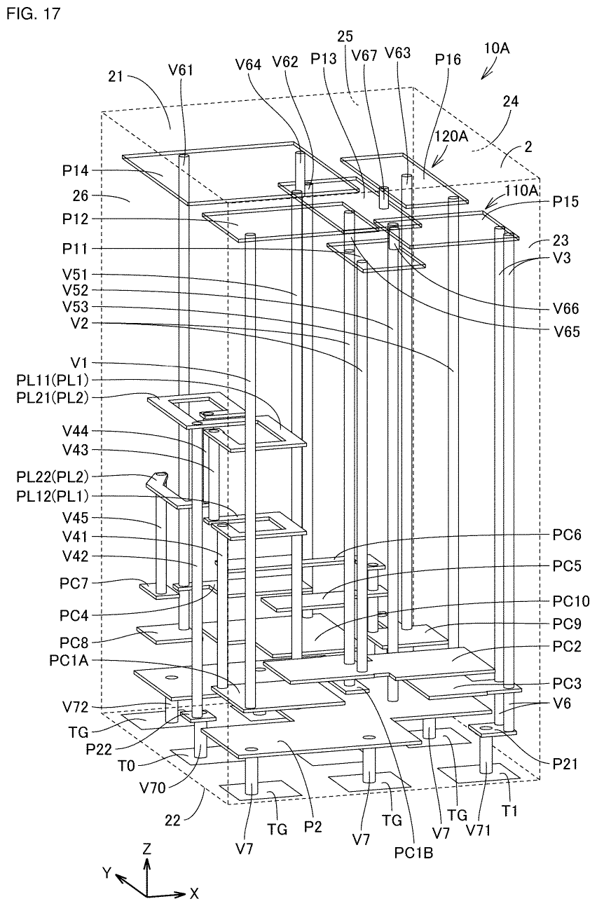

FIG. 17 is a perspective view of a diplexer 10A according to Modification 1 of Example Embodiment 2. Hereinafter, only differences between the diplexer 10A according to Modification 1 of Example Embodiment 2 and the diplexer 1X according to the comparative example will be described, and description of similarities to the diplexer 1X according to the comparative example may be omitted.

When the diplexer 1X according to the comparative example shown in FIG. 1 is compared with the diplexer 10A according to Modification 1 of Example Embodiment 2 shown in FIG. 17, the diplexer 10A differs s from the diplexer 1X according to the comparative example in that an electrode P1 includes a plurality of electrodes P11, P12, and P15, and a via V65 connecting the electrode P11 and the electrode P12 and a via V66 connecting the electrode P11 and the electrode P15 are provided in a low pass filter 110A.

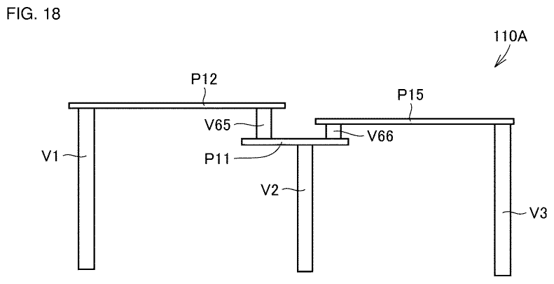

FIG. 18 is a schematic cross-sectional view of a portion of the low pass filter 110A according to Modification 1 of Example Embodiment 2. As shown in FIGS. 17 and 18, the low pass filter 110A includes the electrodes P11, P12, and P15, and vias V1, V2, V3, V65, and V66.

The electrode P12 is an example of a “first electrode portion”, and is a flat plate-shaped electrode provided near an upper surface 21 among a plurality of dielectric layers. The electrode P11 is an example of a “second electrode portion”, and is a flat plate-shaped electrode provided below the electrode P12 in the lamination direction. The electrode P15 is an example of a “third electrode portion”, and is a flat plate-shaped electrode provided above the electrode P11 in the lamination direction. In other words, the electrode corresponding to the “first electrode” has a three-layer structure including the plurality of electrodes P11, P12, and P15.

The via V1 is an example of a “first via”, and connects the electrode P12 and a capacitor electrode PC1A. The via V2 is an example of a “second via”, and connects the electrode P11 and a capacitor electrode PC2. The via V3 is an example of a “third via”, and connects the electrode P11 and a capacitor electrode PC3. The via V65 is an example of a “first connection via”, and connects the electrode P11 and the electrode P12. The via V66 is an example of a “second connection via”, and connects the electrode P11 and the electrode P15. The vias V65 and V66 are shorter than the vias V1, V2, and V3.

Furthermore, in the low pass filter 110A, the vias V1, V2, and V3 are connected to the electrodes P12, P11, and P15, respectively. In this case, the number of holes formed in each of the electrodes P12 and P15 is two, and the number of holes formed in the electrode P11 is one.

By providing steps between the separate electrodes P12, P11, and P15, only two holes are provided in the electrode P12 to connect the two vias V1 and V65, only one hole is formed in the electrode P11 to connect one via V2, and only two holes are provided in the electrode P15 to connect the two vias V3 and V66. This makes it possible to reduce the number of holes formed in one sheet, compared to the case where three holes are provided in the electrode P1 to connect the three vias V1, V2, and V3, as in the low pass filter 11X according to the comparative example. This can reduce bleeding during electrode printing when conductive paste is applied for printing to form the electrode pattern of the electrode P11, electrode P12, or electrode P15 on the sheet, resulting in good frequency characteristics.

By adjusting the distance between the electrode P11 and the electrode P12, the lengths of the vias V1, V2, and V65 can be adjusted. Similarly, by adjusting the distance between the electrode P11 and the electrode P15, the lengths of the vias V3 and V66 can be adjusted. As a result, the inductance of the low pass filter 110A can be adjusted. By making the vias V65 and V66 shorter than the vias V1, V2, and V3, the vias V1, V2, and V3 can be appropriately lengthened, thus ensuring appropriate inductance of the low pass filter 110A. Furthermore, by dividing the electrode into three layers, the area per layer in the planar direction can be reduced, and dimensional variations in the electrodes can be “reduced or prevented.

The diplexer 10A according to Modification 1 of Example Embodiment 2 described above is characterized by the configuration of the low pass filter 110A. However, a high pass filter 120A may also have the same characteristics as the low pass filter 110A. In other words, an LC filter according to an example embodiment of the present disclosure is not limited to functioning as the low pass filter 110A, but may also function as the high pass filter 120A.

When the diplexer 1X according to the comparative example shown in FIG. 1 is compared with the diplexer 10A according to Modification 1 of Example Embodiment 2 shown in FIG. 17, the diplexer 10A differs from the diplexer 1X according to the comparative example in that an electrode P3 includes a plurality of electrodes P13, P14, and P16, and a via V64 connecting the electrode P13 and the electrode P14 and a via V67 connecting the electrode P13 and the electrode P16 are provided in the high pass filter 120A.

The electrode P14 is an example of a “first electrode portion”, and is a flat plate-shaped electrode provided near the upper surface 21 among the plurality of dielectric layers. The electrode P13 is an example of a “second electrode portion”, and is a flat plate-shaped electrode provided below the electrode P14 in the lamination direction. The electrode P16 is an example of a “third electrode portion”, and is a flat plate-shaped electrode provided above the electrode P14 in the lamination direction. In other words, the electrode corresponding to the “first electrode” has a three-layer structure including the plurality of electrodes P13, P14, and P16.

A via V61 is an example of a “first via”, and connects the electrode P14 and a capacitor electrode PC8. A via V62 is an example of a “second via”, and connects the electrode P13 and a capacitor electrode PC10. A via V63 is an example of a “third via”, and connects the electrode P13 and a capacitor electrode PC9. The via V64 is an example of a “first connection via”, and connects the electrode P13 and the electrode P14. The via V67 is an example of a “second connection via”, and connects the electrode P13 and the electrode P16. The vias V64 and V67 are shorter than the vias V61, V62, and V63.

Furthermore, in the high pass filter 120A, the vias V61, V62, and V63 are connected to the electrodes P13, P14, and P16, respectively. In this case, the number of holes formed in each of the electrodes P14 and P16 is two, and the number of holes formed in the electrode P13 is one.

By providing steps between the separate electrodes P13, P14, and P16, only two holes are provided in the electrode P14 to connect the two vias V61 and V64, only one hole is formed in the electrode P13 to connect one via V62, and only two holes are provided in the electrode P16 to connect the two vias V63 and V67. This makes it possible to reduce the number of holes formed in one sheet, compared to the case where three holes are provided in the electrode P1 to connect the three vias V1, V2, and V3, as in the low pass filter 11X according to the comparative example. This can reduce bleeding during electrode printing when conductive paste is applied for printing to form the electrode pattern of the electrode P13, electrode P14, or electrode P16 on the sheet, resulting in good frequency characteristics.

By adjusting the distance between the electrode P13 and the electrode P14, the lengths of the vias V61, V62, and V64 can be adjusted. Similarly, by adjusting the distance between the electrode P13 and the electrode P16, the lengths of the vias V63 and V67 can be adjusted. As a result, the inductance of the high pass filter 120A can be adjusted. By making the vias V64 and V67 shorter than the vias V61, V62, and V63, the vias V61, V62, and V63 can be appropriately lengthened, thus ensuring appropriate inductance of the high pass filter 120A. Furthermore, by dividing the electrode into three layers, the area per layer in the planar direction can be reduced, and dimensional variations in the electrodes can be “reduced or prevented.

The features of the diplexer 10A according to Modification 1 of Example Embodiment 2 described above may be combined with the features of the diplexer 1 according to Example Embodiment 1 shown in FIGS. 5 to 11. That is, the configuration near the upper surface 21 of the diplexer 10A according to Modification 1 of Example Embodiment 2 may be combined with the configuration near the lower surface 22 of the diplexer 1 according to Example Embodiment 1.

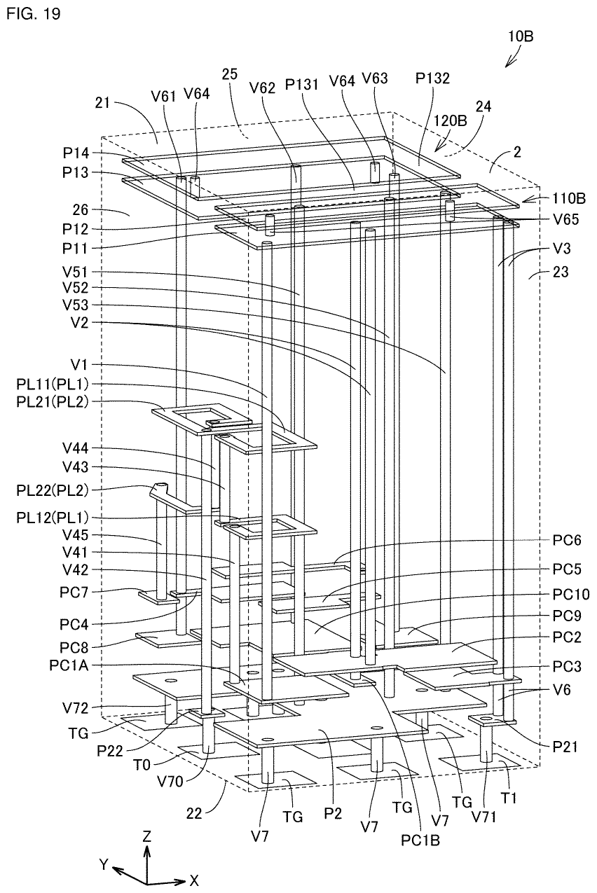

FIG. 19 is a perspective view of a diplexer 10B according to Modification 2 of Example Embodiment 2. Hereinafter, only differences between the diplexer 10B according to Modification 2 of Example Embodiment 2 and the diplexer 1X according to the comparative example will be described, and description of similarities to the diplexer 1X according to the comparative example may be omitted.

When the diplexer 1X according to the comparative example shown in FIG. 1 is compared with the diplexer 10B according to Modification 2 of Example Embodiment 2 shown in FIG. 19, the diplexer 10B differs from the diplexer 1X according to the comparative example in that an electrode P1 includes a plurality of electrodes P11 and P12, and a via V65 connecting the electrode P11 and the electrode P12 is provided in a low pass filter 110B.

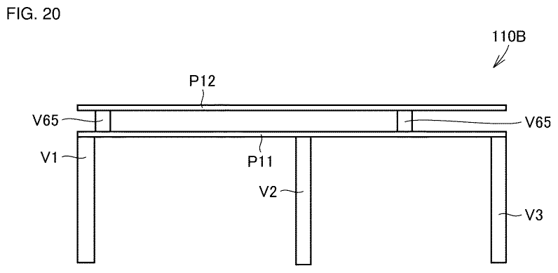

FIG. 20 is a schematic cross-sectional view of a portion of the low pass filter 110B according to Modification 2 of Example Embodiment 2. As shown in FIGS. 19 and 20, the low pass filter 110B includes the electrodes P11 and P12 and vias V1, V2, V3, and V65.

The electrode P12 is an example of a “first electrode portion”, and is a flat plate-shaped electrode provided near an upper surface 21 among a plurality of dielectric layers. The electrode P11 is an example of a “second electrode portion”, and is a flat plate-shaped electrode provided below the electrode P12 in the lamination direction. In other words, the electrode corresponding to the “first electrode” has a two-layer structure including the plurality of electrodes P11 and P12.

The via V1 is an example of a “first via”, and connects the electrode P11 and a capacitor electrode PC1A. The via V2 is an example of a “second via”, and connects the electrode P11 and a capacitor electrode PC2. The via V3 is an example of a “third via”, and connects the electrode P11 and a capacitor electrode PC3. The via V65 is an example of a “first connection via”, and connects the electrode P11 and the electrode P12. The via V65 is shorter than the vias V1, V2, and V3.

Specifically, in the low pass filter 110B, the vias V1, V2, and V3 are connected to the electrode P11. Therefore, the number of holes formed in the electrode P12 is two.

By providing a step between the separate electrodes P11 and P12, only two holes are provided in the electrode P12 to connect the two vias V65. This makes it possible to reduce the number of holes formed in one sheet, compared to the case where three holes are provided in the electrode P1 to connect the three vias V1, V2, and V3, as in the low pass filter 11X according to the comparative example. This can reduce bleeding during electrode printing when conductive paste is applied for printing to form the electrode pattern of the electrode P12 on the sheet, resulting in good frequency characteristics.

By adjusting the distance between the electrode P11 and the electrode P12, the lengths of the vias V1, V2, V3, and V65 can be adjusted. As a result, the inductance of the low pass filter 110B can be adjusted. By making the via V65 shorter than the vias V1, V2, and V3, the vias V1, V2, and V3 can be appropriately lengthened, thus ensuring appropriate inductance of the low pass filter 110B.

The diplexer 10B according to Modification 2 of Example Embodiment 2 described above is characterized by the configuration of the low pass filter 110B. However, a high pass filter 120B may also have the same characteristics as the low pass filter 110B. In other words, an LC filter according to an example embodiment of the present disclosure is not limited to functioning as the low pass filter 110B, but may also function as the high pass filter 120B.

When the diplexer 1X according to the comparative example shown in FIG. 1 is compared with the diplexer 10B according to Modification 2 of Example Embodiment 2 shown in FIG. 19, the diplexer 10B differs from the diplexer 1X in that an electrode P3 includes a plurality of electrodes P13 and P14 and a via V64 connecting the electrode P13 and the electrode P14 is provided in the high pass filter 120B.

The electrode P14 is an example of the “first electrode portion”, and is a flat plate-shaped electrode provided near the upper surface 21 among the plurality of dielectric layers. The electrode P13 is an example of the “second electrode portion”, and is a flat plate-shaped electrode provided below the electrode P14 in the lamination direction. In other words, the electrode corresponding to the “first electrode” has a two-layer structure including the plurality of electrodes P13 and P14.

A via V61 is an example of a “first via”, and connects the electrode P14 and a capacitor electrode PC8. A via V62 is an example of a “second via”, and connects the electrode P14 and a capacitor electrode PC10. A via V63 is an example of a “third via”, and connects the electrode P14 and a capacitor electrode PC9. The via V64 is an example of a “first connection via”, and connects the electrode P13 and the electrode P14. The via V64 is shorter than the vias V61, V62, and V63.

Specifically, in the high pass filter 120B, the vias V61, V62, and V63 are connected to the electrode P13. Therefore, the number of holes formed in the electrode P13 is two.

By providing a step between the separate electrodes P13 and P14, only two holes are provided in the electrode P13 to connect the two vias V64. This makes it possible to reduce the number of holes formed in one sheet, compared to the case where three holes are provided in the electrode P1 to connect the three vias V1, V2, and V3, as in the low pass filter 11X according to the comparative example. This can reduce bleeding during electrode printing when conductive paste is applied for printing to form the electrode pattern of the electrode P13 on the sheet, resulting in good frequency characteristics.

By adjusting the distance between the electrode P13 and the electrode P14, the lengths of the vias V61, V62, V63, and V64 can be adjusted. As a result, the inductance of the high pass filter 120B can be adjusted. By making the via V64 shorter than the vias V61, V62, and V63, the vias V61, V62, and V63 can be appropriately lengthened, thus ensuring appropriate inductance of the high pass filter 120B.

The features of the diplexer 10B according to Modification 2 of Example Embodiment 2 described above may be combined with the features of the diplexer 1 according to Example Embodiment 1 shown in FIGS. 5 to 11. That is, the configuration near the upper surface 21 of the diplexer 10B according to Modification 2 of Example Embodiment 2 may be combined with the configuration near the lower surface 22 of the diplexer 1 according to Example Embodiment 1.

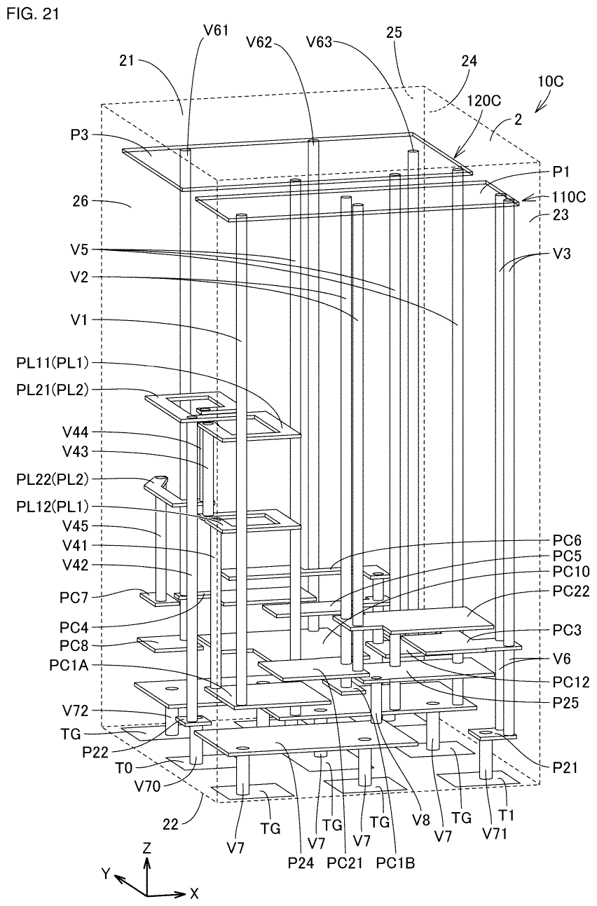

FIG. 21 is a perspective view of a diplexer 10C according to Modification 3 of Example Embodiment 2. Hereinafter, only differences between the diplexer 10C according to Modification 3 of Example Embodiment 2 and the diplexer 1X according to the comparative example will be described, and description of similarities to the diplexer 1X according to the comparative example may be omitted.

When the diplexer 1X according to the comparative example shown in FIG. 1 is compared with the diplexer 10C according to Modification 3 of Example Embodiment 2 shown in FIG. 21, the diplexer 10C differs from the diplexer 1X according to the comparative example in that an electrode P2 includes a plurality of electrodes P24 and P25 and a via V8 connecting the electrode P24 and the electrode P25 is provided in a low pass filter 110C.

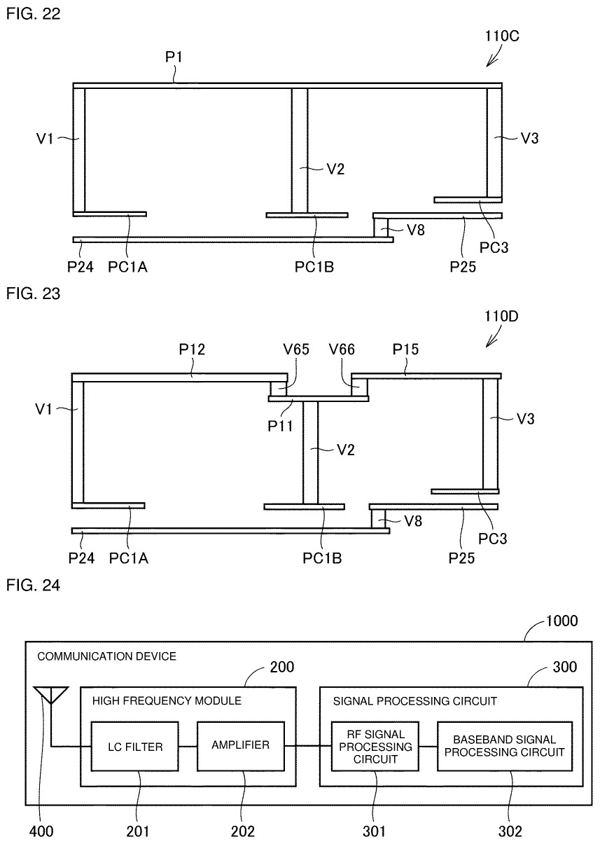

FIG. 22 is a schematic cross-sectional view of a portion of the low pass filter 110C according to Modification 3 of Example Embodiment 2. As shown in FIGS. 21 and 22, the low pass filter 110C includes electrodes P1, P24, and P25, capacitor electrodes PC1A, PC1B, and PC3, and vias V1, V2, V3, and V8.

The electrode P1 is an example of a “first electrode”, and is a flat plate-shaped electrode provided in a first dielectric layer near an upper surface 21 among a plurality of dielectric layers. The electrodes P24 and P25 are an example of a “second electrode”, and are flat plate-shaped electrodes provided in a second dielectric layer near a lower surface 22 among the plurality of dielectric layers. The electrode P24 is provided below the electrode P25 in the lamination direction. In other words, the electrode corresponding to the “second electrode” has a two-layer structure including the plurality of electrodes P24 and P25.

The capacitor electrode PC1A is an example of a “first capacitor electrode”, and is provided in a third dielectric layer between the first dielectric layer in which the electrode P1 is provided and the second dielectric layer in which the electrode P25 is provided. The capacitor electrode PC1B is an example of a “second capacitor electrode”, and is provided in fourth dielectric layer between the first dielectric layer in which the electrode P1 is provided and the third dielectric layer in which the capacitor electrode PC1A is provided. The capacitor electrode PC3 is an example of a “third capacitor electrode”, and is provided in a dielectric layer between the first dielectric layer in which the electrode P1 is provided and the fourth dielectric layer in which the capacitor electrode PC1B is provided.

The via V1 is an example of a “first via”, and connects the electrode P1 and the capacitor electrode PC1A. The via V2 is an example of a “second via”, and connects the electrode P1 and the capacitor electrode PC1B. The via V3 is an example of a “third via”, and connects the electrode P11 and the capacitor electrode PC3.

At least one of the third dielectric layer in which the capacitor electrode PC1A is provided, the fourth dielectric layer in which the capacitor electrode PC1B is provided, and the dielectric layer in which the capacitor electrode PC3 is provided is the same as the second dielectric layer in which the electrode P25 is provided. In the example of FIG. 22, the capacitor electrodes PC1A and PC1B are provided in the same dielectric layer. Furthermore, the capacitor electrodes PC1A and PC1B are provided in the second dielectric layer in which the electrode P25 is provided. That is, in the example of FIG. 22, the second dielectric layer, the third dielectric layer, and the fourth dielectric layer are the same dielectric layer. The capacitor electrode PC3 is provided in the dielectric layer different from the second dielectric layer, the third dielectric layer, and the fourth dielectric layer. Specifically, the capacitor electrode PC3 is provided directly above the electrode P25.

As described above, by dividing the electrode P2 connected to the ground into two layers and providing a ground electrode portion (electrode P25) corresponding to the capacitor electrode PC3 in the same dielectric layer as the capacitor electrodes PC1A and PC1B, the number of laminated layers corresponding to the capacitor electrode PC3 can be reduced. This makes it possible to reduce costs.

Note that not only the dielectric layer in which the capacitor electrode PC3 is provided, but the third dielectric layer in which the capacitor electrode PC1A is provided or the fourth dielectric layer in which the capacitor electrode PC1B is provided may also be the same as the second dielectric layer in which the electrode P25 is provided.

The diplexer 10C according to Modification 3 of Example Embodiment 2 described above is characterized by the configuration of the low pass filter 110C. However, a high pass filter 120C may also have the same characteristics as the low pass filter 110C. In other words, an LC filter according to an example embodiment of the present disclosure is not limited to functioning as the low pass filter 110C, but may also function as the high pass filter 120C.

In this case, a two-layer structure may be achieved by making the electrode P3 correspond to the “first electrode” and the electrode P2 correspond to the “second electrode”. The capacitor electrode PC8 may correspond to the “first capacitor electrode”, the capacitor electrode PC10 may correspond to the “second capacitor electrode”, and the capacitor electrode PC9 may correspond to the “third capacitor electrode”. A via V61 connecting the electrode P3 and the capacitor electrode PC8 may correspond to the “first via”, a via V62 connecting the electrode P3 and the capacitor electrode PC10 may correspond to the “second via”, and a via V63 connecting the electrode P3 and the capacitor electrode PC9 may correspond to the “third via”. At least one of the third dielectric layer in which the capacitor electrode PC8 is provided, the fourth dielectric layer in which the capacitor electrode PC10 is provided, and the dielectric layer in which the capacitor electrode PC9 is provided may be the same as the second dielectric layer in which the upper electrode of the electrode P2 is provided, and the third and fourth dielectric layers may be the same dielectric layer.

The features of the diplexer 10C according to Modification 3 of Example Embodiment 2 described above may be combined with the features of the diplexer 10 according to Example Embodiment 2 shown in FIGS. 14 and 15, the features of the diplexer 10A according to Modification 1 of Example Embodiment 2 shown in FIGS. 16 and 17, or the features of the diplexer 10B according to Modification 2 of Example Embodiment 2 shown in FIGS. 18 and 19. Specifically, the configuration near the lower surface 22 of the diplexer 10C according to Modification 3 of Example Embodiment 2 may be combined with the configuration near the upper surface 21 of the diplexer 10 according to Example Embodiment 2, the diplexer 10A according to Modification 1 of Example Embodiment 2, or the diplexer 10B according to Modification 2 of Example Embodiment 2.

For example, FIG. 23 is a schematic cross-sectional view of a portion of a low pass filter 110D according to Modification 4 of Example Embodiment 2. As shown in FIG. 23, the configuration of the low pass filter 110A according to Modification 1 of Example Embodiment 2 shown in FIG. 18 may be combined with the configuration of the low pass filter 110C according to Modification 3 of Example Embodiment 2 shown in FIG. 22.

FIG. 24 is a block diagram of a high frequency module 200 including an LC filter according to an example embodiment and a communication device 1000. The communication device 1000 is, for example, a mobile terminal such as a smartphone or a wearable terminal such as a smartwatch. As shown in FIG. 24, the communication device 1000 includes the high frequency module 200, a signal processing circuit 300, and an antenna 400.

The high frequency module 200 is, for example, a module compatible with 4G (fourth-generation mobile communications) or 5G (fifth-generation mobile communications) standards. The high frequency module 200 includes an LC filter 201 and an amplifier 202.

The LC filter 201 passes only high frequency signals of a specific frequency among signals (high frequency signals) received from the antenna 400. The LC filter 201 also passes only high frequency signals of a specific frequency among signals (high frequency signals) transmitted from the signal processing circuit 300 and amplified by the amplifier 202, and outputs the signals to the antenna 400. As this LC filter 201, a low pass filter or high pass filter according to Example Embodiments 1 and 2 may be adopted.

The amplifier 202 amplifies, by the amplifier 202, the signals (high frequency signals) received from the antenna 400 and passed through the LC filter 201, and outputs the amplified signals to the signal processing circuit 300. The amplifier 202 also amplifies the signals transmitted from the signal processing circuit 300, and outputs the amplified signals to the LC filter 201.

The signal processing circuit 300 processes high frequency signals (transmitted signals and received signals) passing through the high frequency module 200. The signal processing circuit 300 includes an RF signal processing circuit 301 and a baseband signal processing circuit 302.

The RF signal processing circuit 301 is a radio frequency integrated circuit (RFIC) that performs signal processing on received signals (high-frequency signals). For example, the RF signal processing circuit 301 performs signal processing such as down conversion on the signals received from the high frequency module 200 and outputs the signals to the baseband signal processing circuit 302. The RF signal processing circuit 302 also performs signal processing such as up conversion on the transmitted signals outputted from the baseband signal processing circuit 302 and outputs the signals to the high frequency module 200.

The baseband signal processing circuit 302 is a baseband integrated circuit (BBIC). The baseband signal processing circuit 302 outputs a signal received from the RF signal processing circuit 301 to an internal device. The output signal (received signal) from the baseband signal processing circuit 302 is used as an image signal for image display or as an audio signal for calls. The baseband signal processing circuit 302 also generates a transmission signal based on a baseband signal (for example, audio signal or image signal) inputted from the internal device, and outputs the generated transmission signal to the RF signal processing circuit 302.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An LC filter comprising:
a plurality of laminated dielectric layers;
a flat plate-shaped first electrode provided in a first dielectric layer;
a flat plate-shaped second electrode provided in a second dielectric layer;
a flat plate-shaped first capacitor electrode provided in a third dielectric layer between the first dielectric layer and the second dielectric layer;
a flat plate-shaped second capacitor electrode provided in a fourth dielectric layer between the first dielectric layer and the third dielectric layer;
a flat plate-shaped third capacitor electrode provided in a dielectric layer between the first dielectric layer and the second dielectric layer;
a first via connecting the first electrode and the first capacitor electrode;
a second via connecting the first electrode and the second capacitor electrode; and
a third via connecting the first electrode and the third capacitor electrode; wherein
in plan view of the first capacitor electrode from a lamination direction, the first capacitor electrode overlaps with a portion of each of the second electrode and the second capacitor electrode to define a capacitor between the first capacitor electrode and each of the second electrode and the second capacitor electrode; and
in plan view of the third capacitor electrode from the lamination direction, the third capacitor electrode overlaps with a portion of the second capacitor electrode without overlapping with the second electrode to define a capacitor between the third capacitor electrode and the second capacitor electrode.

2. The LC filter according to claim 1, wherein the third capacitor electrode is provided in the third dielectric layer.

3. The LC filter according to claim 1, wherein the third capacitor electrode is provided in a fifth dielectric layer between the first dielectric layer and the fourth dielectric layer.

4. The LC filter according to claim 1, wherein
the second capacitor electrode includes:
a first capacitor portion that defines a capacitor between the first capacitor portion and the first capacitor electrode; and
a second capacitor portion that defines a capacitor between the second capacitor portion and the third capacitor electrode;
the first capacitor portion is provided in the fourth dielectric layer, and the second capacitor portion is provided in a sixth dielectric layer different from the fourth dielectric layer; and
the fourth dielectric layer is closer to the second dielectric layer in which the second electrode is provided in the lamination direction than the sixth dielectric layer.

5. The LC filter according to claim 1, wherein
the first electrode includes:
a first electrode portion; and
a second electrode portion connected to the first electrode portion through a first connection via; and
at least one of the first via, the second via, and the third via is connected to the second electrode portion.

6. The LC filter according to claim 5, wherein the first connection via is shorter than the first via, the second via, and the third via.

7. The LC filter according to claim 5, wherein other vias different from the at least one via among the first via, the second via, and the third via are connected to the first electrode portion.

8. The LC filter according to claim 5, wherein
the first electrode further includes a third electrode portion connected to the second electrode portion through a second connection via; and
the first via, the second via, and the third via are connected to the first electrode portion, the second electrode portion, and the third electrode portion, respectively.

9. The LC filter according to claim 8, wherein the second connection via is shorter than the first via, the second via, and the third via.

10. The LC filter according to claim 5, wherein the first via, the second via, and the third via are connected to the second electrode portion.

11. The LC filter according to claim 5, wherein
at least one of the third dielectric layer in which the first capacitor electrode is provided, the fourth dielectric layer in which the second capacitor electrode is provided, and the dielectric layer in which the third capacitor electrode is provided is the same as the second dielectric layer in which the second electrode is provided; and
the third dielectric layer and the fourth dielectric layer are the same dielectric layer.

12. The LC filter according to claim 1, wherein the plurality of dielectric layers include ceramic.

13. The LC filter according to claim 1, wherein the LC filter defines and functions as a low pass filter to pass signals in a frequency band lower than a specific frequency.

14. The LC filter according to claim 1, wherein the LC filter defines and functions as a high pass filter to pass signals in a frequency band higher than a specific frequency.

15. A diplexer comprising:
a low pass filter to pass signals in a frequency band lower than a specific frequency; and
a high pass filter to pass signals in a frequency band higher than the specific frequency; wherein
the filter according to claim 1 configured to define and function as at least one of the low pass filter and the high pass filter.

16. A high frequency module comprising:
the LC filter according to claim 1; and
an amplifier to amplify signals passed through the LC filter.

17. The high frequency module according to claim 16, wherein the high frequency module is configured to be compatible with a fourth-generation mobile communications standard or a fifth-generation mobile communications standard.

18. A communication device comprising:
the high frequency module according to claim 16; and
a signal processing circuit to process signals from the high frequency module.

19. The communication device according to claim 18, wherein the high frequency module is configured to be compatible with a fourth-generation mobile communications standard or a fifth-generation mobile communications standard.

20. The communication device according to claim 18, wherein the communication device is a mobile terminal, a smartphone or a wearable terminal.
